(19) United States
(12) Patent Application Publication
(10) Pub. No.: US 2025/0118706 A1
(43) Pub. Date: Apr. 10, 2025

(54) CHIP PACKAGE WITH A THERMAL CARRIER

(71) Applicant: Advanced Micro Devices, Inc., Santa Clara, CA (US)

(72) Inventors: Manish DUBEY, Austin, TX (US); Arsalan ALAM, Austin, TX (US); Hemanth Kumar DHAVALESWARAPU, Austin, TX (US); Chandra Sekhar MANDALAPU, Lehi, UT (US); Sriram CHANDRASEKARAN, Austin, TX (US)

(21) Appl. No.: 18/377,280

(22) Filed: Oct. 5, 2023

(51) Int. Cl. H01L 25/065; H01L 23/00; H01L 23/36; H01L 23/538; H01L 25/00

(52) U.S. Cl. CPC H01L 25/0652; H01L 23/36; H01L 23/5383; H01L 24/08; H01L 25/50; H01L 2224/08145; H01L 2224/08225

(57) ABSTRACT

A chip package and method for fabricating the same are provided that include a IC dies bonded to a thermal carrier having a plurality of metallic pillars. In one example, a chip package includes an interconnect routing structure and a first die disposed on a first surface of the interconnect routing structure. The first die has a circuitry connected to a circuitry of the interconnect routing structure. The chip package also includes a second die at least partially disposed over the first die. The second die has a circuitry connected to the circuitry of the first die. A thermal carrier is bonded on the second die. At least one of the thermal carrier, the first die, or the second die includes a plurality of metallic pillars configured to transfer heat, wherein the plurality of metallic pillars are electrically floating.

### TECHNICAL FIELD

Embodiments of the present invention generally relate to a chip package having a thermal carrier, and in particular, to a chip package having a thermal carrier for dissipating heat away from a die stack.

### BACKGROUND

Electronic devices, such as tablets, computers, copiers, digital cameras, smart phones, control systems, automated teller machines, data centers, artificial intelligence system, and machine learning systems among others, often employ electronic components which leverage chip package assemblies for increased functionality and higher component density. Conventional chip packaging schemes often utilize a package substrate, often in conjunction with a through-silicon-via (TSV) interposer substrate, to enable a plurality of integrated circuit (IC) dies to be mounted to a single package substrate. The IC dies may include memory, logic or other IC devices.

In advanced chip-on-wafer (CoW) chip packages, the integration of stacks of IC dies is becoming increasingly challenging. For example, heat removal from the chip packages remains a challenge when dies are stacked on top of each other. In particular, heat must move through several interfaces before reaching the top surface of the chip package.

Therefore, a need exists for a chip package having improved heat removal features.

### SUMMARY

A chip package and method for fabricating the same are provided that include a IC dies bonded to a thermal carrier having a plurality of metallic pillars. In one example, a chip package includes an interconnect routing structure and a first die disposed on a first surface of the interconnect routing structure. The first die has a circuitry connected to a circuitry of the interconnect routing structure. The chip package also includes a second die at least partially disposed over the first die. The second die has a circuitry connected to the circuitry of the first die. A thermal carrier is bonded on the second die. At least one of the thermal carrier, the first die, or the second die includes a plurality of metallic pillars configured to transfer heat, wherein the plurality of metallic pillars are electrically floating.

In another example, a chip package is provided that includes an interconnect routing structure, a first die and a second die disposed on a first surface of the interconnect routing structure. Each of the first die and the second die has a circuitry connected to a circuitry of the interconnect routing structure. A third die is at least partially disposed over the first die and the second die. The third die has a circuitry connected to the circuitry of the first die and the second die. A thermal carrier mounted on the third die. The thermal carrier includes a plurality of metallic pillars extending from a top surface of the thermal carrier to a bottom surface of the thermal carrier. The plurality of metallic pillars are electrically floating.

A method for forming a chip package includes mounting a plurality of dies to a first carrier. The method also includes mounting a bridge die on two dies of the plurality of dies and electrically connecting the bridge die to the two dies. The method further includes mounting a thermal carrier on the bridge die. Thermal carrier has a plurality of metallic pillars extending from a top surface to a bottom surface of the thermal carrier, and the metallic pillars are electrically floating. After attaching the thermal carrier, the first carrier is removed from the plurality of dies. Thereafter, the plurality of dies are attached to a package substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for forming a chip package having a thermal carrier.

FIGS. 2-7 are a schematic representation of one example of the chip package during different stages of fabrication according to the method of FIG. 1.

FIG. 8 is a schematic view of a chip package including a fusion bond having a reduced thickness, according to some embodiments.

FIG. 9 is a partial enlarged view of the chip package of FIG. 8 illustrating a hybrid bond between a silicon spacer and a die.

FIG. 10 is a schematic view of a chip package including a plurality of metallic pillars, according to some embodiments.

FIG. 11 is a schematic view of a chip package including a plurality of metallic pillars, according to some embodiments.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A chip package and method for fabricating the same are provided that improve heat dissipation from a top surface of IC dies, according to some embodiments. A thermal carrier having a plurality of metallic pillars are disposed on the top surface of the IC dies and the metallic pillars are. In some embodiments, the metallic pillars are formed in the dies, silicon spacers, or both. In some embodiments, the thickness of one or more fusion bonds between the dies and the carrier are reduced to facilitate heat removal from the dies. In some embodiments, a redistribution layer is formed on a 8006579_2 3 bottom surface of the thermal carrier. The redistribution layer is bonded to the top surface of the IC dies. Heat from the IC dies may be removed via the redistribution layer, up the metallic pillars, and out of the thermal carrier.

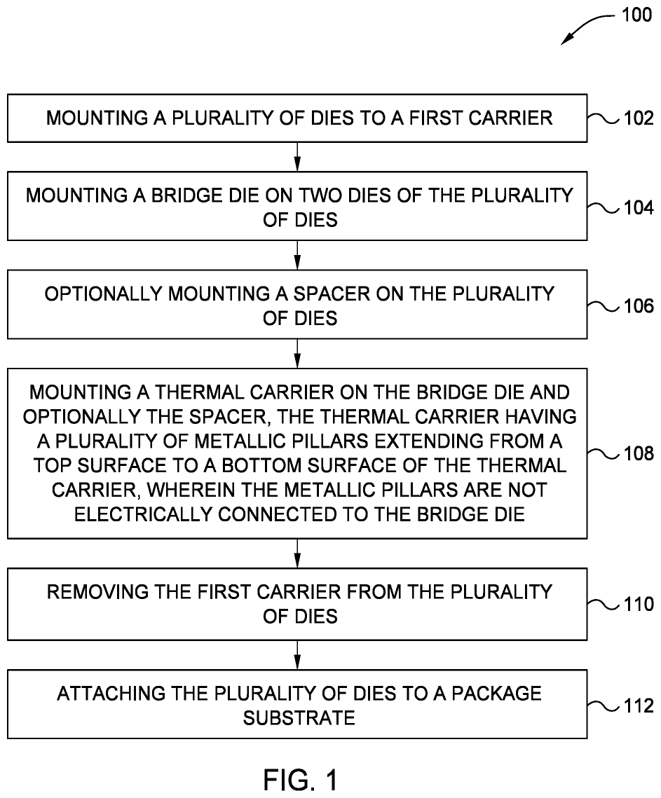

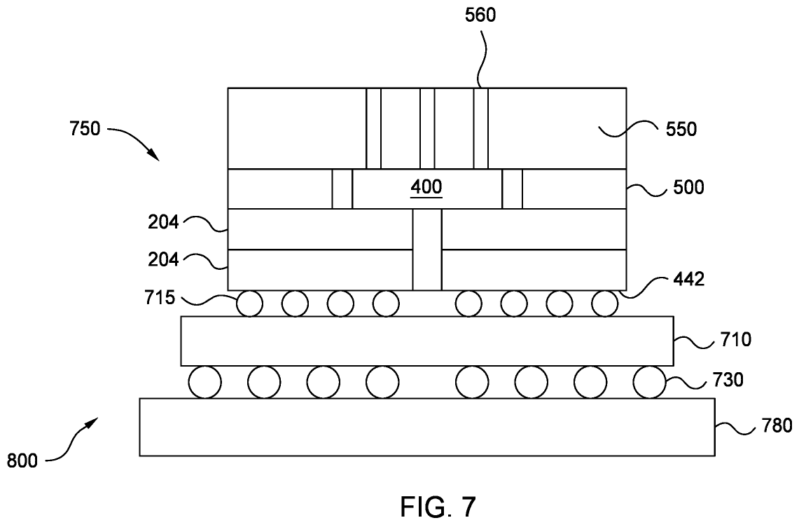

Turning now to FIG. 1, a flow diagram of a method 100 for forming a chip package having thermal carrier is provided. The chip package may be configured as illustrated in FIG. 7, or have another suitable configuration.

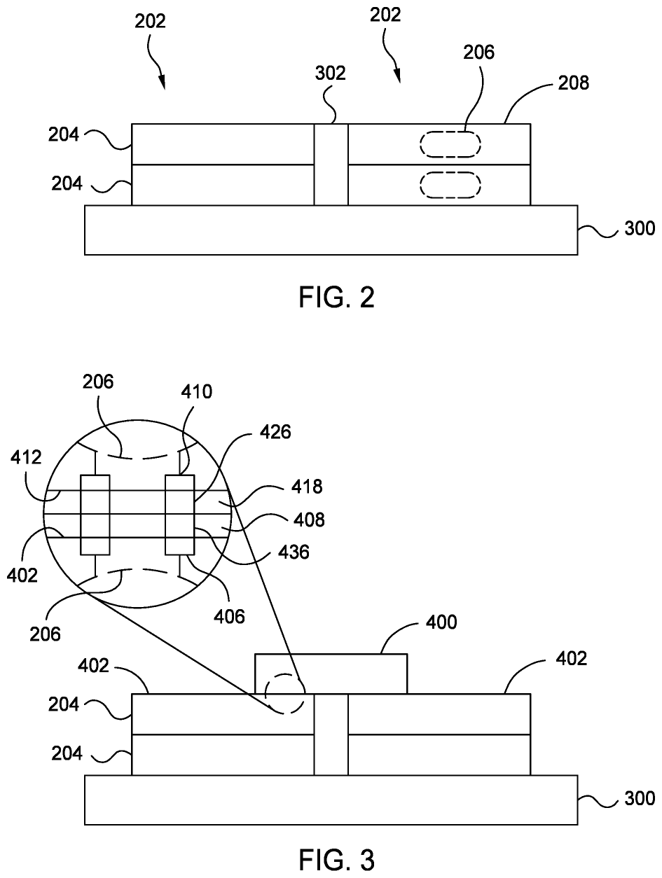

FIGS. 2-7 are a schematic representation of one example of the chip package during different stages of fabrication according to the method 100 of FIG. 1.

The method 100 begins at operation 102 by mounting a plurality of integrated circuit (IC) dies 204 to a first carrier 300 as illustrated in FIG. 2. In some embodiments, the IC dies 204 may be a plurality of die stacks 202. Each die stack 202 includes a plurality of integrated circuit (IC) dies 204 that are vertically stacked. Each die stack 202 may include one or more IC dies 204. In die stacks 202 having two more IC dies 204, a top die is vertically stacked on top of a bottom die (with optionally intervening dies disposed in between the top and bottom dies). Optionally, one or more or all of the IC dies 204 within one or more of the die stacks 202 may be a chiplet. Although the example depicted in FIG. 2 shows two die stacks 202, the chip package may include one, three, four or more die stacks 202.

Each of the IC dies 204 include a die body 208 having functional circuitry 206 formed in therein. The functional circuitry 206 may include block random access memory (BRAM), UltraRAM (URAM), digital signal processing (DSP) blocks, configurable logic elements (CLEs), and the like. The IC dies 204 may be, but are not limited to, programmable logic devices, such as field programmable gate arrays (FPGA), memory devices, such as high bandwidth memory (HBM), optical devices, processors or other IC logic structures. The IC dies 204 may optionally include optical devices such as photo-detectors, lasers, optical sources, and the like. In some examples, at least one of the IC dies 204 is a logic die having math processor (also known as math engine) circuitry for accelerating machine-learning math operations in hardware, such as self-driving cars, artificial intelligence and data-center neural-network applications. In another example, at least one of the IC dies 204 is a logic die, while the other IC dies 204 within the die stack 202 are memory devices.

The IC dies 204 within the die stack 202 are mechanically and electrically coupled together so that the functional circuitry 206 of one IC die 204 is in direct communication with the functional circuitry 206 of the vertically adjacent IC die 204. The vertically adjacent IC dies 204 may be coupled via solder connections, hybrid bonding, fusion bonding, or other suitable technique. In the example depicted in FIG. 2, the adjacent IC dies 204 are coupled by hybrid bonding techniques. Hybrid bonding includes forming non-metal to non-metal bonds using fusion bonding, and forming metal-to-metal bonds across the adjacent IC dies 204. The metal-to-metal bonds may be formed using pressure and heat to form eutectic metal bonds. In one example, a hybrid bond is formed by bonding the dielectric materials surrounding the bond pads on each IC die 204 to first secure the IC dies 204 together, followed by an interfusion of the metal materials of the bond pads of the facing IC dies 204 to create the electric interconnect between the functional circuitry 206 of the one IC die 204 and the functional circuitry 206 of the vertically adjacent IC die 204.

Although two IC die stacks 202 are illustrated in FIG. 2 mounted to the first carrier 300, the first carrier 300 may be the size of a wafer such that significantly more than two IC die stacks 202 are mounted to the first carrier 300. The IC die stacks 202 may be mounted to the first carrier 300 using a temporary adhesive, such as a die attach film or tape. The first carrier 300 may be any suitable rigid substrate to which the last IC die 204 of the die stack 202 may be temporally secured during the later described hybrid bonding to a thermal carrier. In one example, the first carrier 300 is made of silicon. In another example, the first carrier 300 is a metal plate, such as an aluminum plate, or a glass or glass reinforced plastic plate.

After the IC die stacks 202 are attached to the first carrier 300, a dielectric filler 302 is disposed between the IC die stacks 202, filling the gaps between the IC die stacks 202. The dielectric filler 302 may be an oxide, polymer, or other suitable material.

The method 100 continues to operation 104. At operation 104, a bridge die 400 is mounted to the IC dies 204 furthest from the first carrier 300 (e.g., the top dies 204) of adjacent IC die stacks 202, as illustrated in FIG. 3. The bridge die 400 is hybrid bonded to the exposed top surface 402 of IC dies 204. The top surface 402 of IC dies 204 may optionally be thinned, for example by grinding, prior to attaching the bridge die 400. To facilitate hybrid bonding of the bridge die 400 to the exposed top surface 402 of IC dies 204, a bond pad 426 is formed on a respective contact pad 410 on the bottom surface of the bridge die 400. Each of the bond pads 426 is separated by a dielectric layer 418 suitable for hybrid bonding. The dielectric layer 418 is deposited on the non-conductive bottom surface around the bond pads 426 of the bridge die 400. Materials suitable for the dielectric layer 418 include oxides, thermal oxides, SiO₂, SiN, SiCN, polybenzoxazole (PBO), polyimide (PI), benzocyclobutene (BCB), among others. Similarly, a bond pad 436 is formed on a respective contact pad 406 on the top surface 402 of the IC dies 204. Each of the bond pads 436 is separated by a dielectric layer 408 suitable for hybrid bonding. The dielectric layer 408 is deposited on the non-conductive top surface around the bond pads 436 of the IC dies 204. Materials suitable for the dielectric layer 408 include oxides, thermal oxides, SiO₂, SiN, SiCN, polybenzoxazole (PBO), polyimide (PI), benzocyclobutene (BCB), among others. The dielectric layers 408, 418 allow the bridge die 400 to initially bond, for example by fusion bonding, to the exposed top surface 402 of IC dies 204. This is then followed by forming metal-to-metal bonds between the bond pads 426 of the bridge die 400 and the bond pads 436 on each IC die 204 using pressure and heat to form eutectic metal bonds.

The hybrid bonding of the bridge die 400 to the exposed top surface 402 of each IC die 204 connects routing (e.g., solid state circuitry) formed within the bridge die 400 via contact pads 410 to the contact pads 406 of each IC die 204. Thus, the functional circuitry 206 of the horizontally adjacent IC dies 204 are connected through the routing formed within the bridge die 400. The hybrid bonding of the bridge die 400 provides a significantly denser pitch of connections between the contact pads 406 of the IC die 204 and the contact pads 410 of the bridge die 400. As a result, the communication bandwidth between the bridge die 400 and IC dies 204 hybrid bonded thereto is significantly greater than conventional devices that utilize solder-based connections between dies in adjacent die stacks.

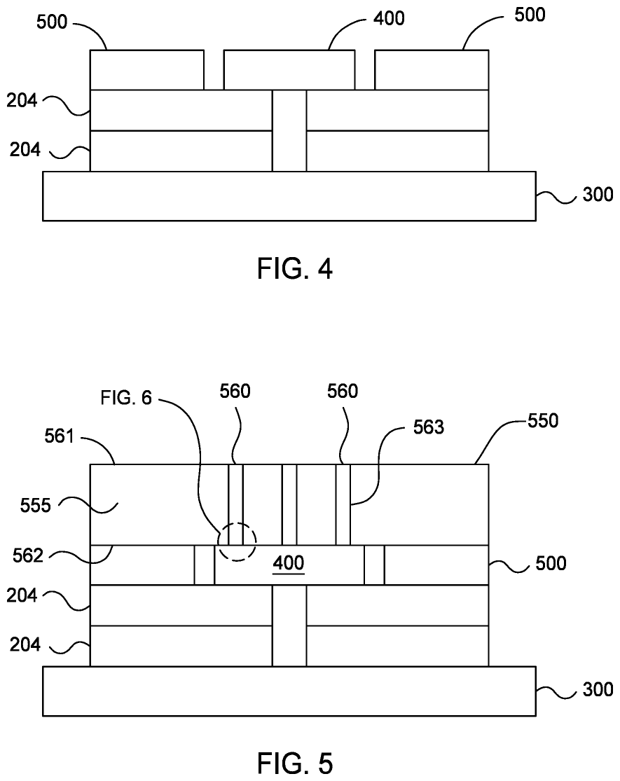

At an optional operation 106, spacers are mounted to the exposed top surface 402 of the IC dies 204, as illustrated in FIG. 4. In FIG. 4, the spacers are embodied as additional structures. The additional structures may be additional IC dies 500 similar to the IC dies 204 or other suitable processor dies, memory dies, dummy dies, passive devices or chiplets. The circuitry of the additional IC dies 204 communicates with the circuitry 206 of the adjacent IC die 204.

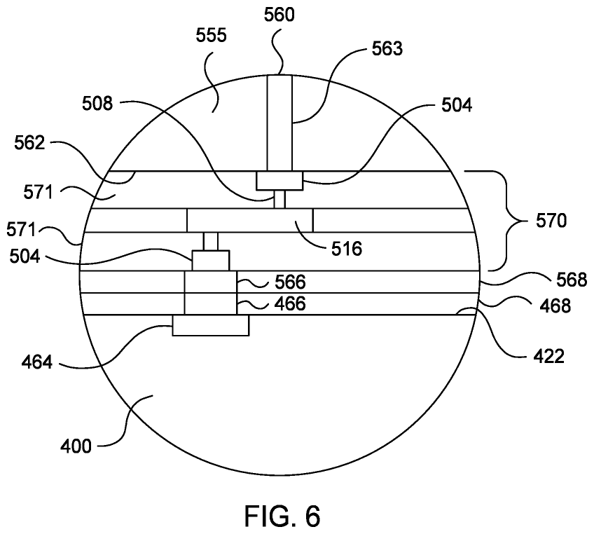

At operation 108, a thermal carrier 550 is mounted on uppermost dies 400, 500, which are the bridge die 400 and the top IC dies 500 as shown in FIG. 5. FIG. 6 illustrates an exploded, partial view of the thermal carrier 550 mounted to the bridge die 400. In one embodiment, the thermal carrier 550 include a carrier body 555 and has no functional circuitry. The carrier body 555 may be a silicon body. The thermal carrier 550 is hybrid bonded to the top surface of the dies 400, 500. Because the thermal carrier 550 has no functional circuitry, the thermal carrier 550 is electrically floating, e.g., not in electrical communication with the functional circuitry 206 of the dies 400, 500 therebelow.

The thermal carrier 550 includes a plurality of metallic pillars 560 formed through the carrier body 555. In this example, the thermal carrier 550 includes three metallic pillars 560 that extend from the top surface 561 of the carrier body 555 to the bottom surface 562 of the carrier body. The metallic pillars 560 provide a thermal path to direct heat away from the top of the IC dies. The metallic pillars 560 may comprises copper or other suitable metal. In one embodiment, the metallic pillars 560 are formed by fabricating a through opening 563 in the carrier body 555 using deep reactive ion etching, laser drilling, or suitable methods for forming the through opening 563. The metallic pillars 560 are formed by copper plating. In this example, each of the metallic pillars 560 is a single plated column. The metallic pillars 560 are electrically floating, e.g., not grounded or connected to any functional circuitry. The metallic pillars 560 are located in a central area of the thermal carrier 550. It is contemplated the thermal carrier 550 may have any suitable number of metallic pillars 560 or width to dissipate heat. The cross-sectional shape of the metallic pillars 560 is circular, but may be polygonal or other suitable shape. The metallic pillars 560 may be positioned at any suitable location in the thermal carrier 550, for example, equally spaced across the thermal carrier 550 or located where more heat removal is needed.

In one embodiment, the thermal carrier 550 includes a thermal routing structure formed on the bottom surface 562 of the carrier body 555. In this example, the thermal routing structure is embodied as a redistribution layer 570. The redistribution layer 570 includes three or more patterned metal layers disposed between dielectric layers 571. The patterned metal layers are used to form contact pads 504 and lines 506 that are interconnected by vias 508 to form thermal routing circuitry through the redistribution layer 570. The thermal routing circuitry through the redistribution layer 570 is utilized to thermally connect the metallic pillars 560 to the dies 400, 500. In FIG. 6, one pad 504 of the redistribution layer 570 terminates at the metallic pillars 560, while the other pad 504 of the thermal routing circuitry of the redistribution layer 570 is thermally connected to the bridge die 400. In this manner, the redistribution layer 570 is formed directly on the exposed bottom surface 562 of the thermal carrier 550 without any intervening solder connections. The redistribution layer 570 beneficially transfers heat from across the dies 400, 500 toward the central region where the metallic pillars 560 are located. The metallic pillars 560 provide a more efficient heat path for heat transfer through the thermal carrier 550. Additionally, due to the centrally located metallic pillars 560, the edges of the thermal carrier 550 receives less heat from the dies 400, 500. It is contemplated the metallic pillars 560 may be located across the carrier body 555 to facilitate heat transfer away from different locations of the chip package as needed.

In one embodiment, the thermal carrier 550 is mounted to the exposed top surface 402 of the dies 400, 500 using hybrid bonding. In another embodiment, the thermal carrier 550 is mounted to the top surface 402 of the dies 400, 500 using solder connection or other suitable technique. To facilitate hybrid bonding of the thermal carrier 550 to the dies 400, 500, a bond pad 566 is formed on a respective contact pad 504 exposed on the bottom surface of the redistribution layer 570. Each of the bond pads 566 is separated by a dielectric layer 568 suitable for hybrid bonding. The dielectric layer 568 is deposited on the exposed bottom surface around the bond pads 566 of redistribution layer 570. Materials suitable for the dielectric layer 568 include oxides, thermal oxides, SiO₂, SIN, SiCN, polybenzoxazole (PBO), polyimide (PI), benzocyclobutene (BCB), among others.

To prepare the dies 400, 500 for hybrid bonding, a plurality of bond pads 466 are formed on the top surface 402 of the dies 400, 500. The bond pads 466 are electrically floating, e.g., not grounded or connected to the functional circuitry of the respective dies 400, 500. As such, the bond pads 466 may be formed on any suitable portion of the top surface 402, e.g., not on a contact pad. Optionally, a plurality of contact pads 464 are formed on the top surface 422 of the dies 400, 500 for receiving the bond pads 466. If used, the contact pads 464 are electrically floating, e.g., not grounded or connected to the functional circuitry of the respective dies 400, 500. Each of the bond pads 466 are separated by a dielectric layer 468 suitable for hybrid bonding. The dielectric layer 468 is deposited on the exposed top surface 422 of the dies 400, 500. Materials suitable for the dielectric layer 468 include oxides, thermal oxides, SiO₂, SiN, SiCN, polybenzoxazole (PBO), polyimide (PI), benzocyclobutene (BCB), among others. During hybrid bonding, the dielectric layer 468 of the dies 400, 500 initially bonds, for example by fusion bonding, to the dielectric layer 568 of the thermal carrier 550. This is then followed by forming metal-to-metal bonds between the bond pads 566 of the thermal carrier 550 and the bond pads 466 on each die 400, 500 using pressure and heat to form eutectic metal bonds.

The hybrid bonding forms thermal pathways between the dies 400, 500 and the thermal carrier 550 to dissipate heat from the dies 400, 500. The thermal pathways extend from the bond pads 566, to the redistribution layer 570, and through the metallic pillars 560. Although heat may also dissipate through the carrier body 555, the metallic pillars 560 provide more efficient pathways for removing heat from the dies 204, 400, 500 due to copper having better thermal conductivity than silicon. In some embodiments, a lid (not shown) is disposed over the top of the thermal carrier 550. Heat leaving the metallic pillars 560 are transferred to the lid. Optionally, a thermal interface material is disposed between the thermal carrier and the lid.

At operation 110, the first carrier 300 is removed. The exposed bottom surfaces 442 of the first IC dies 204 of the die stacks 202 have microbumps 715 plated thereon for attachment to a substrate 710 of the chip package, such as an interposer or package substrate. See FIG. 7. The first IC dies 204 may be electrically and physically connected to the substrate 710 via hybrid bonding, solder connection, or suitable technique. Optionally, an underfill is disposed between the first IC dies 204 and the substrate 710.

At operation 112, solder balls 730 are formed on the substrate 710, as illustrated in FIG. 7. The solder balls 900 are used to connect the substrate 710 of the chip package 750 to a printed circuit board (PCB) 780 to form an electronic device 800. In other embodiments, the substrate 710 may be in the form of an interposer substrate and coupled by the solder balls 730 to a package substrate, rather than a PCB 780, to form the chip package 750.

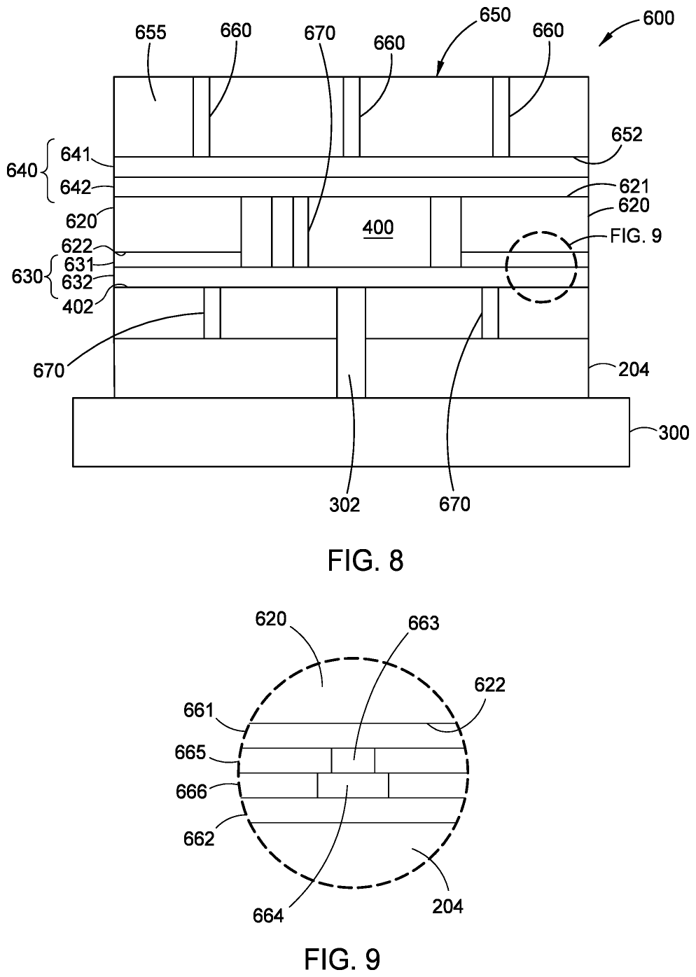

FIG. 8 illustrates another embodiment of a chip package 600. Similar to the chip package shown in FIG. 5, the chip package 600 includes a plurality of integrated circuit (IC) dies 204 mounted to a first carrier 300. In some embodiments, the IC dies 204 may be a plurality of die stacks 202. Each die stack 202 may include one or more IC dies 204. In die stacks 202 having two more IC dies 204, a top die is vertically stacked on top of a bottom die (with optionally intervening dies disposed in between the top and bottom dies). Although the example depicted in FIG. 8 shows two die stacks 202, the chip package may include one, three, four or more die stacks 202.

Each of the IC dies 204 include a functional circuitry (e.g., functional circuitry 206) formed in therein. The functional circuitry 206 may include block random access memory (BRAM), UltraRAM (URAM), digital signal processing (DSP) blocks, configurable logic elements (CLEs), and the like. The IC dies 204 may be, but are not limited to, programmable logic devices, such as field programmable gate arrays (FPGA), memory devices, such as high band-width memory (HBM), optical devices, processors or other IC logic structures. The IC dies 204 may optionally include optical devices such as photo-detectors, lasers, optical sources, and the like. In some examples, at least one of the IC dies 204 is a logic die having math processor (also known as math engine) circuitry for accelerating machine-learning math operations in hardware, such as self-driving cars, artificial intelligence and data-center neural-network applications. In another example, at least one of the IC dies 204 is a logic die, while the other IC dies 204 within the die stack 202 are memory devices.

The IC dies 204 within the die stack are mechanically and electrically coupled together so that the functional circuitry of one IC die 204 is in direct communication with the functional circuitry of the vertically adjacent IC die 204. The vertically adjacent IC dies 204 may be coupled via solder connections, hybrid bonding, fusion bonding, or other suitable technique. In the example depicted in FIG. 8, the adjacent IC dies 204 are coupled by hybrid bonding techniques. Hybrid bonding includes forming non-metal to non-metal bonds using fusion bonding, and forming metal-to-metal bonds across the adjacent IC dies 204. The metal-to-metal bonds may be formed using pressure and heat to form eutectic metal bonds. In one example, a hybrid bond is formed by bonding the dielectric materials surrounding the bond pads on each IC die 204 to first secure the IC dies 204 together, followed by an interfusion of the metal materials of the bond pads of the facing IC dies 204 to create the electric interconnect between the functional circuitry of the one IC die 204 and the functional circuitry of the vertically adjacent IC die 204.

In some embodiments, the first carrier 300 may be the size of a wafer such that significantly more than two IC die stacks are mounted to the first carrier 300. The IC die stacks may be mounted to the first carrier 300 using a temporary adhesive, such as a die attach film or tape. The first carrier 300 may be any suitable rigid substrate to which the last IC die 204 of the die stack may be temporally secured during the later described hybrid bonding to a thermal carrier. In one example, the first carrier 300 is made of silicon. In another example, the first carrier 300 is a metal plate, such as an aluminum plate, or a glass or glass reinforced plastic plate.

A dielectric filler 302 is disposed between the IC die stacks 202, filling the gaps between the IC die stacks. The dielectric filler 302 may be an oxide, polymer, or other suitable material.

A bridge die 400 is mounted to the IC dies 204 furthest from the first carrier 300 (e.g., the top dies 204) of adjacent IC die stacks. In this embodiment, the bridge die 400 is hybrid bonded to the exposed top surface 402 of IC dies 204. The bridge die 400 may be hybrid bonded in a similar manner as discussed and shown in FIG. 3, and will not be discussed further in detail. The hybrid bonding of the bridge die 400 to the exposed top surface 402 of each IC die 204 connects routing (e.g., solid state circuitry) formed within the bridge die 400 to each IC die 204. Thus, the functional circuitry of the horizontally adjacent IC dies 204 are connected through the routing formed within the bridge die 400. In some embodiments, the bridge die 400 is fusion bonded to the IC dies 204.

In some embodiments, silicon spacers 620 are mounted to the exposed top surface 402 of the IC dies 204. The silicon spacers 620 include a silicon body and have no functional circuitry. Because the silicon spacers 620 have no functional circuitry, the silicon spacers 620 are electrically floating, e.g., not in electrical communication with the functional circuitry of the dies 204 therebelow.

In one embodiment, the silicon spacers 620 are fusion bonded to the dies 204. The fusion bonds 630 have a reduced thickness to facilitate heat dissipation. For example, during fusion bonding, an upper oxide layer 631 may form on the bottom surface 622 of the silicon spacers 620, and a lower oxide layer 632 may form on the top surface 402 of the die 204. The thickness of the fusion bond 630 is the combined thickness of the upper oxide layer 631 and the lower oxide layer 632. In this embodiment, the total thickness is reduced by at least 30%, at least 40%, from 30% to 50%, or from 40% to 50%. In one example, the thickness of the fusion bond 630 may be reduced during deposition of at least one of the upper and lower oxide layers 631, 632 that forms the fusion bond. The oxide layers 631, 632 may be deposited using plasma enhanced chemical vapor deposition (PECVD). The thickness of the oxide layers 631, 632 may be reduced by controlling the PECVD process. The thinner fusion bond 630 may have a thickness from 1.7 micron to 2.4 micron, which is a reduced thickness relative to a standard fusion bond thickness. It is contemplated the upper oxide layer 631 and the lower oxide layer 632 may be reduced by the same or different thicknesses. For example, the upper oxide layer 631 may be reduced more than the lower oxide layer 632. In some embodiments, the silicon spacers 620 are bonded to the dies 204 using plasma activated fusion bond, which uses a lower annealing temperature, such as below 400° C.

In yet another embodiment, the silicon spacers 620 are bonded to the dies 204 using a hybrid bond to facilitate heat dissipation. As shown in the example of FIG. 9, an optional first oxide layer 661 is formed on the bottom surface 622 of the silicon spacer 620. A bond pad 663 is formed below the first oxide layer 661. Each of the bond pads 663 is separated by a dielectric layer 665 suitable for hybrid bonding. The dielectric layer 665 is deposited below the first oxide layer 661 around the bond pads 663. Materials suitable for the dielectric layer 665 include oxides, thermal oxides, SiO₂, SiN, SiCN, polybenzoxazole (PBO), polyimide (PI), benzocyclobutene (BCB), among others. Similarly, an optional second oxide layer 662 is formed on the top surface 402 of the dies 204. A bond pad 664 is formed on the second oxide layer 662. The bond pads 664 are not connected to the functional circuitry of the dies 204. Each of the bond pads 664 is separated by a dielectric layer 666 suitable for hybrid bonding. The dielectric layer 666 is deposited on the second oxide layer 662 around the bond pads 664. Materials suitable for the dielectric layer 666 include oxides, thermal oxides, SiO₂, SiN, SiCN, polybenzoxazole (PBO), polyimide (PI), benzocyclobutene (BCB), among others. The dielectric layers 665, 666 allow the silicon spacers 620 to initially bond, for example by fusion bonding, to the exposed top surface 402 of IC dies 204. This is then followed by forming metal-to-metal bonds between the bond pads 663 of the silicon spacers 620 and the bond pads 664 on each IC die 204 using pressure and heat to form eutectic metal bonds. The hybrid bonding of the silicon spacer 620 to the dies 204 improves the heat transfer from the dies 204 to the silicon spacer 620.

In some embodiments, a silicon carrier 650 is mounted on the bridge die 400 and the silicon spacers 620. In one embodiment, the silicon carrier 650 includes a carrier body 655 and has no functional circuitry. The carrier body 655 may be a silicon body. In one example, the silicon carrier 650 may be the thermal carrier 550 shown in FIG. 5. In one embodiment, the silicon carrier 650 is fusion bonded to the bridge die 400 and the silicon spacers 620. The fusion bond 670 has a reduced thickness to facilitate heat dissipation. For example, during fusion bonding, an upper oxide layer 641 may form on the bottom surface 652 of the silicon carrier 650, and a lower oxide layer 642 may form on the top surface 621 of the silicon spacers 620 and the bridge die 400. The thickness of the fusion bond 640 is the combined thickness of the upper oxide layer 641 and the lower oxide layer 642. In this embodiment, the total thickness of the fusion bond 640 is reduced by at least 30%, at least 50%, from 30% to 80%, or from 40% to 80%. In one example, the thickness of the fusion bond 640 may be reduced during deposition of at least one of the upper and lower oxide layers 641, 642 that forms the fusion bond. The oxide layers 641, 642 may be deposited using plasma enhanced chemical vapor deposition (PECVD). The thickness of the oxide layers 641, 642 may be reduced by controlling the PECVD process. The thinner fusion bond 640 may have a thickness from 0.35 micron to 0.7 micron, which is a reduced thickness relative to a standard fusion bond thickness. It is contemplated the upper oxide layer 641 and the lower oxide layer 642 may be reduced by the same or different thicknesses. For example, the upper oxide layer 641 may be reduced more than the lower oxide layer 642. In some embodiments, the silicon carrier 650 is bonded to the bridge die 400 and the silicon spacers 620 using plasma activated fusion bond, which uses a lower annealing temperature, such as below 400° C. It is contemplated the thinner fusion bond 640 can be use with or without thinning the fusion bond 630 between the silicon spacers 620 and the dies 204 or the hybrid bond between the silicon spacers 620 and the dies 204. For example, a fusion bond 640 having reduced thickness can be used with a hybrid bond between the silicon spacers 620 and the dies 204. In another example, a fusion bond 640 having reduced thickness can be used in combination with a reduced fusion bond 630 between the silicon spacers 620 and the dies 204.

In another embodiment, the silicon carrier 650 is hybrid bonded to the bridge die 400 and the silicon spacers 620. The hybrid bond may be performed in a manner similar to the hybrid bond show in FIG. 6. This hybrid bond may be used with or without thinning the fusion bond 630 between the silicon spacers 620 and the dies 204 or the hybrid bond between the silicon spacers 620 and the dies 204.

In another embodiment, the silicon carrier 650 optionally includes a plurality of metallic pillars 660. The metallic pillars 660 may be the metallic pillars 560 shown in FIG. 6. For example, the metallic pillars 660 may be coupled to the silicon spacers 620 using a hybrid bond and optionally a redistribution layer. The metallic pillars 660 are not grounded or connected to any of the functional circuitry of the chip package 600. As shown in FIG. 8, the metallic pillars 660 may be spaced across the body of silicon carrier 650. In this example, the metallic pillars 660 extend from the top surface to the bottom surface of the silicon carrier 650. In another example, the metallic pillars 660 partially extend through the silicon carrier 650, such as from the bottom surface to a portion of the silicon carrier 650. The metallic pillars 660 provide a thermal path to direct heat away from the top of the bridge die 400 and the silicon spacers 620. The metallic pillars 660 may comprises copper or other suitable metal. In one embodiment, the metallic pillars 660 are formed by fabricating a through opening in the silicon carrier 650 using deep reactive ion etching, laser drilling, or suitable methods for forming the through opening. The metallic pillars 660 are formed by copper plating. In this example, each of the metallic pillars 660 is a single plated column. It is contemplated the silicon carrier 650 may have any suitable number of metallic pillars 660 or width to dissipate heat. The cross-sectional shape of the metallic pillars 660 is circular, but may be polygonal or other suitable shape. The metallic pillars 660 may be positioned at any suitable location in the silicon carrier 650, for example, centrally located in the silicon carrier 650 or located where more heat removal is needed.

In another embodiment, one or more metallic pillars 670 may be formed in one or more of the IC dies 204 and the bridge die 400 to improve heat dissipation. The metallic pillars 670 are not grounded or connected to any of the functional circuitry of the IC dies 204 or the bridge die 400. The chip package 600 may include metallic pillars 670, metallic pillars 660, or both.

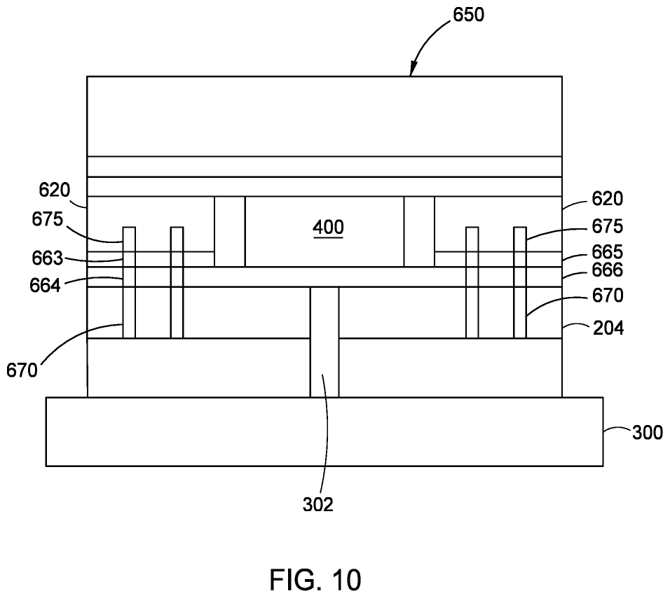

In another embodiment, one or more metallic pillars 670 may be connected to metallic pillars 675 formed in the silicon spacer 620, as illustrated in FIG. 10. In this embodiment, the silicon spacer 620 is hybrid bonded to the IC dies 204. The metallic pillars 670 in the IC dies 204 are connected to the bond pads 664 between the dielectric layer 666. The metallic pillars 675 formed in the silicon spacers 620 are connected to the bond pads 663 between the dielectric layer 665. The metallic pillars 670, 675 are not connected to the functional circuitry of the IC dies 204. As shown, the metallic pillars 675 extend from the bottom surface 622 to at least a portion of the silicon spacer 620, but may extend up to the top surface of the silicon spacer 620.

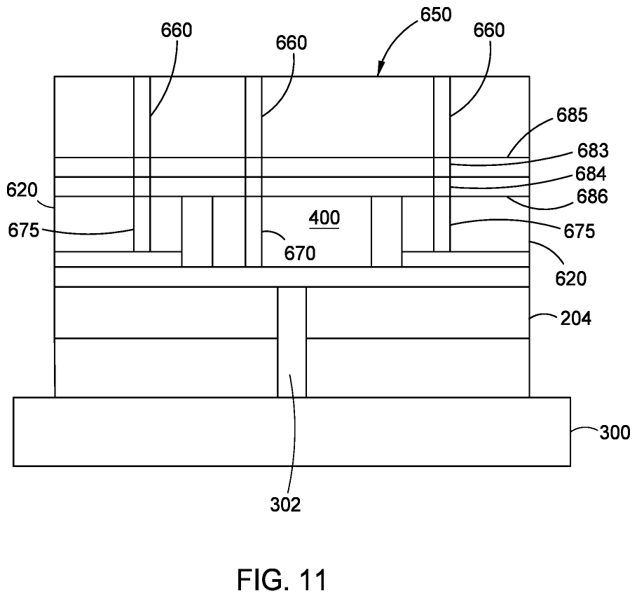

In another embodiment, one or more metallic pillars 660 in the silicon carrier 650 may be connected to one or more of the metallic pillars 670 in the bridge die 400 and the metallic pillars 675 in the silicon spacers 620, as illustrated in FIG. 11. In this embodiment, the silicon carrier 650 is hybrid bonded to the bridge die 400 and the silicon spacers 620. For example, the hybrid bond includes a bond pad 683 formed below the silicon carrier 650. Each of the bond pads 683 is separated by a dielectric layer 685 suitable for hybrid bonding. The dielectric layer 685 is deposited below the silicon carrier 650 around the bond pads 683. Similarly, a bond pad 684 is formed on the bridge die 400 and the silicon spacers 620. The bond pads 684 are not connected to the functional circuitry of the bridge die 400. Each of the bond pads 684 is separated by a dielectric layer 686 suitable for hybrid bonding. The dielectric layer 686 is deposited on the bridge die 400 and the silicon spacers 620 around the bond pads 684. The dielectric layers 685, 686 bond, for example by fusion bonding, and the bond pads 683, 684 are bonded using pressure and heat to form eutectic metal bonds.

The metallic pillars 670 in the bridge die 400 and the metallic pillars 675 in the silicon spacers 620 are connected to the bond pads 684 between the dielectric layer 686. The metallic pillars 660 in the silicon carrier 650 are connected to the bond pads 683 between the dielectric layer 685. The metallic pillars 670, 675 are not connected to the functional circuitry of the IC dies 204.

Embodiments of the present disclosure provide efficient heat transfer pathways that advantageously remove heat from lower conductive interfacial layers of a stacked chip package. In some embodiments, the present disclosure also provide heat transfer pathways that move the heat to the central region of the chip package, thereby minimizing heat damage to the thermal interface materials located at the edge of the IC dies. In this manner, embodiments of the present disclosure addresses one or more reliability concerns of stacked chip packages. Embodiments of the present disclosure may be used for wafer-on-wager stacking, chip-on-wafer stacking N-tier stacking, non-3D stacked configurations, and other suitable chip configurations.

It is contemplated the one or more metallic pillars 560, 660, 670, 675 may be provided in the chip package 600 in any suitable combination. For example, one or more of the metallic pillars 560, 660, 670, 675 may be formed in at least one of the silicon carrier 650, the silicon spacer 620, the bridge die 400, or the IC dies 204. In some embodiments, the metallic pillars 560, 660, 670, 675 may be used in combination with hybrid bonding, a redistribution layer, or a thinner fusion layer. In some embodiments, structures in the chip package may be attached using a thinner fusion bond, hybrid bond, or both to improve heat dissipation.

A chip package and method for fabricating the same are provided that include a IC dies bonded to a thermal carrier having a plurality of metallic pillars. In one example, a chip package includes an interconnect routing structure and a first die disposed on a first surface of the interconnect routing structure. The first die has a circuitry connected to a circuitry of the interconnect routing structure. The chip package also includes a second die at least partially disposed over the first die. The second die has a circuitry connected to the circuitry of the first die. A thermal carrier is bonded on the second die. At least one of the thermal carrier, the first die, or the second die includes a plurality of metallic pillars configured to transfer heat, wherein the plurality of metallic pillars are electrically floating. In some embodiments, the circuitries of the dies and the interconnect routing structure are functional circuitries. In some embodiments, the plurality of metallic pillars are not connected to the functional circuitry of the first die and the second die.

While the foregoing is directed to embodiments of the present invention, other and further embodiments of the invention may be devised without departing from the basic scope thereof, and the scope thereof is determined by the claims that follow.

What is claimed is:

1. A chip package, comprising:
an interconnect routing structure;
a first die disposed on a first surface of the interconnect routing structure, the first die having a circuitry connected to a circuitry of the interconnect routing structure;
a second die at least partially disposed over the first die, the second die having circuitry connected to the circuitry of the first die; and
a thermal carrier bonded on the second die, wherein at least one of the thermal carrier, the first die, or the second die includes a plurality of metallic pillars configured to transfer heat, wherein the plurality of metallic pillars are electrically floating.

2. The chip package of claim 1, further comprising:
a third die disposed on the first surface of the interconnect routing structure, the circuitry of the second die connected to the circuitry of the interconnect routing structure, and the second die is at least partially disposed over the third die.

3. The chip package of claim 1, wherein the thermal carrier is bonded to the second die using a fusion bond, the fusion bond having reduced thickness.

4. The chip package of claim 1, further comprising a silicon spacer disposed between the thermal carrier and the first die, wherein the silicon spacer is bonded to the first die using a fusion bond, the fusion bond having reduced thickness.

5. The chip package of claim 1, wherein the first die includes the plurality of metallic pillars.

6. The chip package of claim 1, wherein each of the plurality of metallic pillars comprises a single plated column.

7. The chip package of claim 1, wherein the thermal carrier is bonded to the second die using hybrid bonding.

8. The chip package of claim 7, wherein the second die includes bond pads for hybrid bonding, and the bond pads are electrically floating.

9. The chip package of claim 1, wherein the thermal carrier comprises silicon.

10. The chip package of claim 1, wherein the interconnect routing structure is a package substrate.

11. The chip package of claim 1, further comprising a redistribution layer disposed on a bottom surface of the thermal carrier.

12. The chip package of claim 11, wherein the redistribution layer is hybrid bonded to the second die.

13. A chip package, comprising:
an interconnect routing structure;
a first die disposed on a first surface of the interconnect routing structure, the first die having circuitry connected to a circuitry of the interconnect routing structure;
a second die disposed on the first surface of the interconnect routing structure, the second die having circuitry connected to the circuitry of the interconnect routing structure;
a third die at least partially disposed over the first die and the second die, the third die having a circuitry connected to the circuitry of the first die and the second die; and
a thermal carrier mounted on the third die, the thermal carrier having a plurality of metallic pillars extending from a top surface of the thermal carrier to a bottom surface of the thermal carrier, wherein the plurality of metallic pillars are electrically floating.

14. The chip package of claim 13, further comprising:
a silicon spacer mounted to at least one of the first die and the second die.

15. The chip package of claim 14, wherein the silicon spacer is mounted to the first die or the second die using a fusion bond having reduced thickness.

16. The chip package of claim 13, wherein each of the plurality of metallic pillars comprise a single plated column.

17. The chip package of claim 16, wherein the plurality of metallic pillars comprise copper.

18. A method for forming a chip package, the method comprising:
mounting a plurality of dies to a first carrier;
mounting a bridge die on two dies of the plurality of dies, the bridge die electrically connected to the two dies;
mounting a thermal carrier on the bridge die, the thermal carrier having a plurality of metallic pillars extending from a top surface to a bottom surface of the thermal carrier, wherein the metallic pillars are electrically floating;
removing the first carrier from the plurality of dies; and
attaching the plurality of dies to a package substrate.

19. The method of claim 18, wherein the thermal carrier is mounted to the bridge die using a fusion bond having reduced thickness.

20. The method of claim 19, wherein the thermal carrier is hybrid bonded to the bridge die.
